(19) United States
(12) Patent Application Publication
(10) Pub. No.: US 2001/0014082 A1
(43) Pub. Date: Aug. 16, 2001

(54) Device capable of setting operating conditions, method of setting operating conditions and test method

(76) Inventor: Hiroshi Tanaka, Tokorozawa (JP)

Correspondence Address: STAAS & HALSEY LLP, 700 11TH STREET, NW, SUITE 500, WASHINGTON, DC, 20001, US

(21) Appl. No.: 09/757,537

(22) Filed: Jan. 11, 2001

(30) Foreign Application Priority Data
Jan. 12, 2000 (JP) 2000-003919

(51) Int. Cl. G01R 31/08

(52) U.S. Cl. 370/250

(57) ABSTRACT

A device control module reads in conditions of switches, such as front panel switches, when an operator selects a test mode. The device control module stores a predetermined conditions of the switches, and when the read-in conditions of the switches satisfy a predetermined conditions, the device control module notifies a result to the operator. The result can be notified to the operator by turning on and off a display, such as an LED. When the test result satisfies a predetermined condition, the display could be turned off. While the test result does not satisfy a predetermined condition, the display could be turned on.

### CROSS REFERENCE TO RELATED APPLICATIONS

The contents of 2000-003919, filed Jan. 12, 2000 in Japan, to which this application claims priority, are incorporated herein by reference.

### BACKGROUND OF THE INVENTION

1. Field of the invention

The present invention relates to test methods used in the evaluation of devices, such as data transmission devices, and to methods of setting various types of operating conditions easily and without error. The present invention further relates to a data transmission device or other device that is capable of setting operating conditions.

2. Description of the Related Art

Many devices have switches, such as setting switches, for setting operating conditions of the device. Before shipping devices, the devices must be tested to determine whether or not the setting switches have been shorted.

As an example of such a device, data transmission devices usually have setting switches, and may have some switches on a front panel for selecting an operation mode. A tester is placed against each switch, one at a time, to perform a test for shorting of these switches.

Further, at the stage of evaluating the device, the setting switches have to be set manually for the various operating conditions, including timing settings, transmission speed settings, etc.

In this way, traditional testing operations have been performed manually, and have caused problems because they were so time-consuming. Also, the manual setting of the operating conditions became a source of testing error.

In particular, data transmission devices usually provide a plurality of data transmission speeds for data transmission. In order to evaluate the devices, a counter test is done to determine if any error during data transmission occurs. To submit a counter test, a number of operating conditions has to be set to the data transmission device. In fact, the counter test had to be conducted at various data transmission speeds and an operator has to set up different operating conditions for each of different transmission speeds. If these operating conditions are set manually, they also contributed to testing error.

### SUMMARY OF THE INVENTION

The present invention solves the above-mentioned problems of the related art.

An object of the present invention is to provide evaluation functions in testing modes while preventing time-consuming procedures and setting errors.

To solve the aforementioned problems, the test method of the present invention reads in a state of the settings of setting switches and determines whether or not the state of the settings that was read in matches a pre-determined state. The results of the determination are then sent to an external module.

More particularly, the test method of the present invention, which is also referred to as a notification method, includes a display such as an LED (light emitting diode) or other device such as a display. If the read-in state of the settings matches a pre-determined state, the display is turned off, thus notifying the user of the test results.

The present invention also assigns respective operating conditions of the setting switches in advance, determines which of the setting switches is on at the time of testing, and, based on that determination, sets up the operating conditions of the device for the corresponding setting switches.

The present invention setting switches that assign the operating conditions in advance and, when the operating conditions of the settings are read in from an external recording medium, the operating conditions of those setting switches are set up in accordance with their content. The operating conditions are set easily and without errors using the present invention.

In addition to being equipped with setting switches that assign the operating conditions in advance, the present invention detects the presence of an external recording medium. When there is an external recording medium present, the operating conditions are read in from the external recording medium and assigned to the setting switches. When there is no external recording medium present, the present invention sets up the operating conditions on a device based on the settings that the user has selected in advance with the setting switches.

The present invention is a test method of a device having a plurality of switches. The test method of the present invention comprises reading a state of the switches, determining whether the read state of the switches satisfies a predetermined state, and notifying the results of the determination.

Moreover, the present invention is a device capable of setting operating conditions. The device of the present invention comprises a setting switch to which an operating condition is assigned, a unit reading content stored in a recording medium, and a unit assigning operating conditions included in the content read from the recording medium to the setting switch.

In addition, the present invention is a data transmission device comprising a plurality of switches in which a different testing mode is assigned to each of the switches, a device controller connected to the switches, and an external medium control unit controlled by the device controller. The device controller controls an operation of the data transmission device, and the external medium control unit reads information recorded within an external recording medium.

These together with other objects and advantages which will be subsequently apparent, reside in the details of construction and operation as more fully hereinafter described and claimed, reference being had to the accompanying drawings forming a part hereof, wherein like numerals refer to like parts throughout.

### BRIEF DESCRIPTION OF THE DRAWINGS

FIG. 1 is a diagram showing a data transmission device configuration based on an embodiment of the present invention.

FIG. 2 is a diagram showing an example of front panel switches of a data transmission device of the embodiment of the present invention shown in FIG. 1.

FIG. 3 is a diagram describing the setting switches of the data transmission device of the embodiment of the present invention.

FIG. 4 is a diagram describing the state of the setting switches during the line connection check run by an embodiment of the present invention.

FIG. 5A is a diagram describing the state of the front panel switches during a line connection check run by an embodiment of the present invention.

FIG. 5B is a diagram of a device control module read-in state.

FIG. 6 is a flow chart of the line connection short check of an embodiment of the present invention.

FIG. 7A is a diagram showing a procedure for the line connection short check of an embodiment of the present invention.

FIG. 7B shows conditions of front panel switches and setting switches during the line connection short check as shown in FIG. 7A.

FIG. 8 is a diagram showing an example of the operating conditions assigned by the front panel switches of an embodiment of the present invention.

FIG. 9 is a flow chart showing a counter-test process of an embodiment of the present invention.

FIG. 10 is a diagram showing the data transmission device configuration where an external recording medium has been inserted in an embodiment of the present invention.

FIG. 11 is a diagram showing a set up process of the operating conditions using an external recording medium in an embodiment of the present invention.

FIG. 12 is a flow chart showing the set up process of the operating conditions using an external recording medium in an embodiment of the present invention.

FIG. 13A is a flow chart showing another process for setting up the operating conditions using an external recording medium in an embodiment of the present invention.

FIG. 13B is a continuation of the flow chart of FIG. 13A showing another process for setting up the operating conditions using an external recording medium.

### DESCRIPTION OF THE PREFERRED EMBODIMENTS

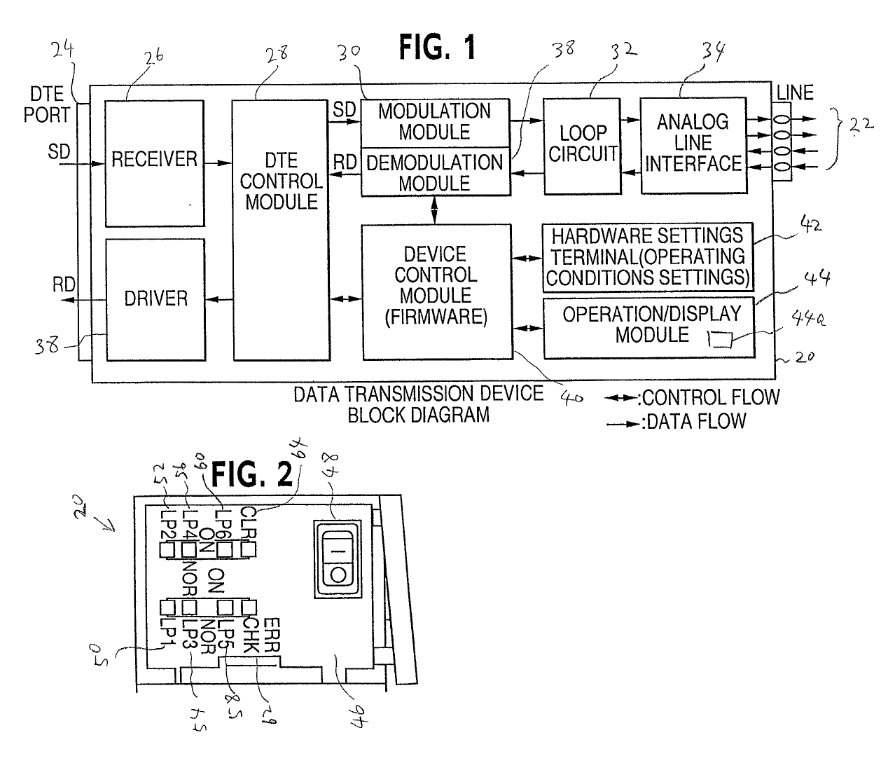

FIG. 1 is a diagram showing the internal configuration of a data transmission device 20 based on an embodiment of the present invention. The data transmission device 20 shown in FIG. 1 is, for example, a modem, or other type of data transmission device.

Communications lines 22 are connected to one side of the data transmission device 20, and a data terminal (DTE, not shown in FIG. 1) is connected to a DTE port 24. Send data (SD) transmitted from the data terminal enters the data transmission device 20 from the DTE port 24, and is transmitted to a DTE control module 28 through receiver 26. SD then enters a modulation module 30, and is modulated by the modulation module 30. Next, after SD has been modulated in the modulation module 30, SD is transmitted to communication lines 22 through a loop circuit 32 and an analog line interface 34.

At the same time, a signal received from the communication lines 22 enters a demodulation module 38 through the analog line interface 34 and the loop circuit 32, and is demodulated. A received data (RD) signal, which is the demodulated data, is transmitted to the DTE control module 28. Then RD is output from the DTE port 24 to the data terminal through a driver 38.

A device control module 40 comprises firmware to control the DTE control module 28 and the modulation module 30/demodulation module 38. The data transmission device 20 includes a hardware setting terminal 42 which set up operating conditions of the data transmission device 20. The data transmission device 20 also includes an operation/display module 44.

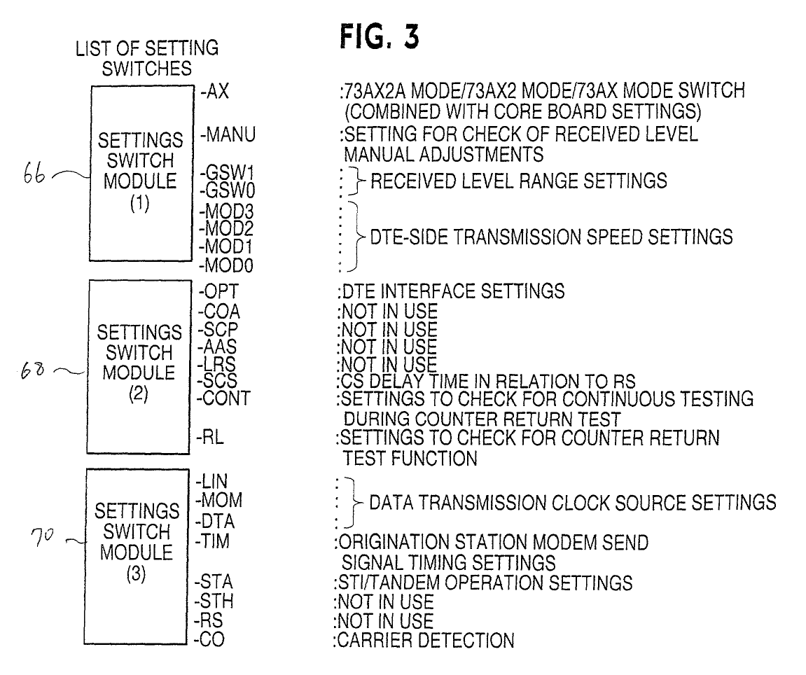

FIG. 2 shows an example of a front panel 46 of the data transmission device 20 of the embodiment of the present invention, which forms a part of operation/display module 44 shown in FIG. 1. As shown in FIG. 2, the front panel 46 includes a power supply switch 48 and switches 50-64 (there are eight switches shown in FIG. 2). Of those switches, switches LP1 50, LP2 52, LP3 54, LP4 56, LP5 58 and LP6 60 are switches for indicating counter tests between a transmission device connected to the other side of the communication lines 22. Each of these switches corresponds to different types of counter tests, and an operator selects one of the switches 50-60 to control the data transmission device 20 to perform a selected counter test. The data transmission device 20 also includes an error check switch (“ERR CHK”) 62, and a clear switch (“CLR”) 64.

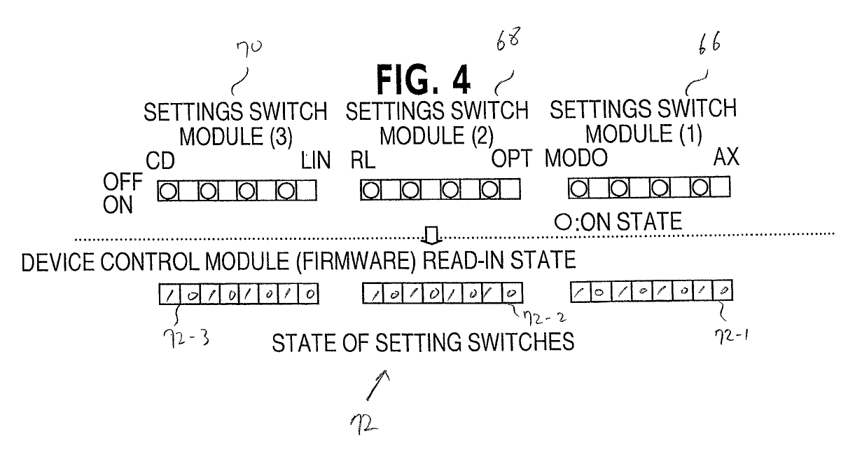

FIG. 3 shows setting switch modules of the embodiment of the present invention, which are included in hardware settings terminal 42 shown in FIG. 1. As shown in FIG. 3, the data transmission device 20 of the present invention comprises three setting switch modules 66, 68, 70. Each of these setting switch modules 66,68,70 includes switches to set up desired operating mode or conditions of the data transmission device 20. An example of operation conditions assigned to each of the switches is shown in FIG. 3.

A setting switch module (1) 66 includes eight switches (AX, MANU, GSW1, GSW0, MOD3, MOD2, MOD1 and MOD0). Switch AX selects an operating mode of the data transmission device 20 thorough hardware settings terminal 42. Switch MANU sets a necessity of manual adjustments of a received signal level. Switches GSW1 and GSW2 set a range of levels of signal received from the other data transmission device. Switches MOD 3 through MOD 0 set transmission speed of the data terminal 20.

A setting switch module (2) 68 also includes eight switches, OPT, COA, SCP, AAS, LRS, SCS, CONT and RL. Among of these, switches COA, SCP, AAS, and LRS are not used for setting operating modes or conditions. Switch OPT sets a DTE interface by interfacing to hardware settings terminal 42. Switch SCS sets CS delay-time in relation to RS. Switches CONT sets whether it is necessary to continue with the counter test. Switch RL sets counter test function, Further, a setting switch module (3) 70 includes eight switches, LIN, MOM, DTA, TIM, STA, STH, RS and CO. Switches LIN, MOM and DTA set a clock source for a data transmission. Switch TIM sets send signal timing of an origination station modem. Switch CO sets carrier detection, and switches STH and RS are not used for setting purposes.

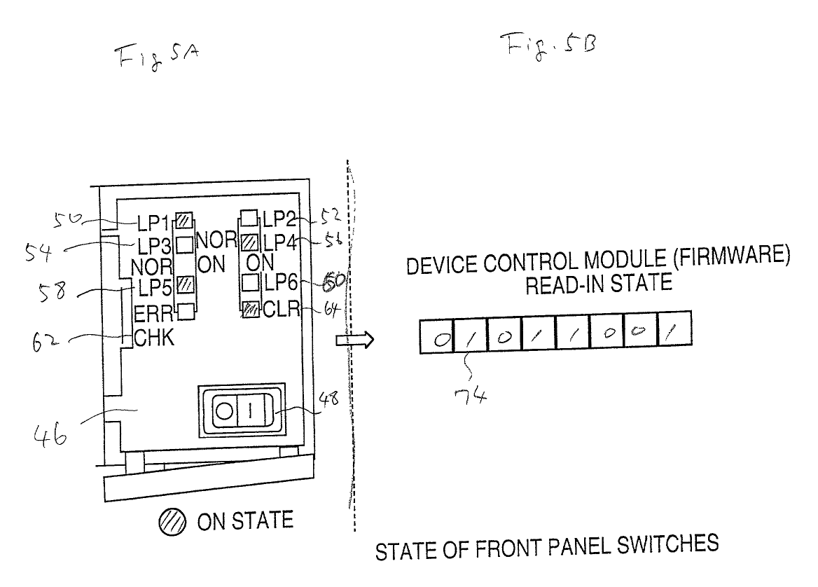

The data transmission device 20 of the present invention checks to determine whether the wiring of these switches is shorted, as a test mode, as explained with reference to FIGS. 4-13B.

FIG. 4 is a diagram showing an example of a setting of the setting switch modules 66, 68, 70 when a test mode is operated. When the test mode is operated, the setting switches of each setting switch modules 66, 68, 70 are set up to alternate between being on and being off as shown in FIG. 4. The setting switches are alternated between being on and being off because this test mode is for checking short circuit of switches.

FIG. 4 also shows an example of a device control module read-in state 72, which includes three registers 72-1, 72-2 and 72-3. This shows how the device control module 40 reads in the state of setting switches 66, 68, 70. The register 72-1 relates to the setting switch module 66, the register 72-2 relates to the setting switch module 68, and register 72-3 relates to the setting module 70. FIG. 4 shows an example that the device control module 40 could correctly read in states of each of switches. Numbers shown within each box denote how the device control module 40 determines a state of each switch: “1” denotes an on-state, and “0” denotes an off-state.

When the switches are wired correctly, a bit series alternating between “1” (the on state) and “0” (the off state) is read by the device control module 40, as shown in FIG. 4. Meanwhile, when the device control module 40 reads in a bit series other than the ones shown in FIG. 4, although setting switches are in the state as shown in FIG. 4, the device control module 40 determines that the wiring of any of the switches 66, 68, 70 is shorted.

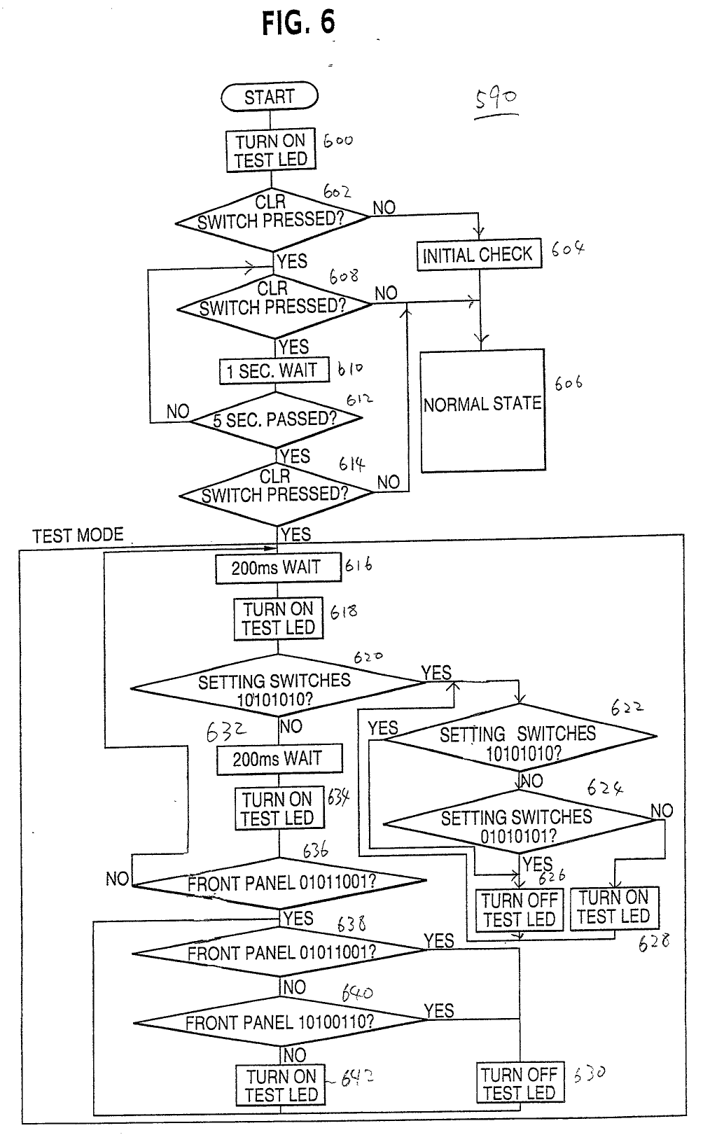

FIG. 5A shows an example of setting of the front panel switch 46 when a test mode of the data transmission device 20 of the present invention is operated. Similar to FIG. 4, eight panel switches of the front panel switches 46 are set to alternate between on and off, as shown in FIG. 5A. The device control module 40 reads in the state of each switch.

An example of the device control module read-in state 74 is shown in FIG. 5B. If the device control module 40 reads in states of each switch correctly, the read-in state of “0101 1001” appears (“0” and “1” are not appearing alternatively).

The data transmission device 20 of this embodiment comprises a test LED 44a as a part of display module 44. The test LED 44a notifies the test results to an operator. When the data transmission device 20 is shifted to a test mode, the test LED 44a turns on. Then the setting switches or the front panel switches are set alternately to on and off by an operator. When the device control module 40 reads in the state of these switches as set up, the test LED 44a turns off to notify that the test is done.

If the data read in by the device control module 40 does not correspond to the state of the settings in question, the test LED 44a will remain on, in which case the user is notified that the wiring is shorted, or the settings of the switches are wrong.

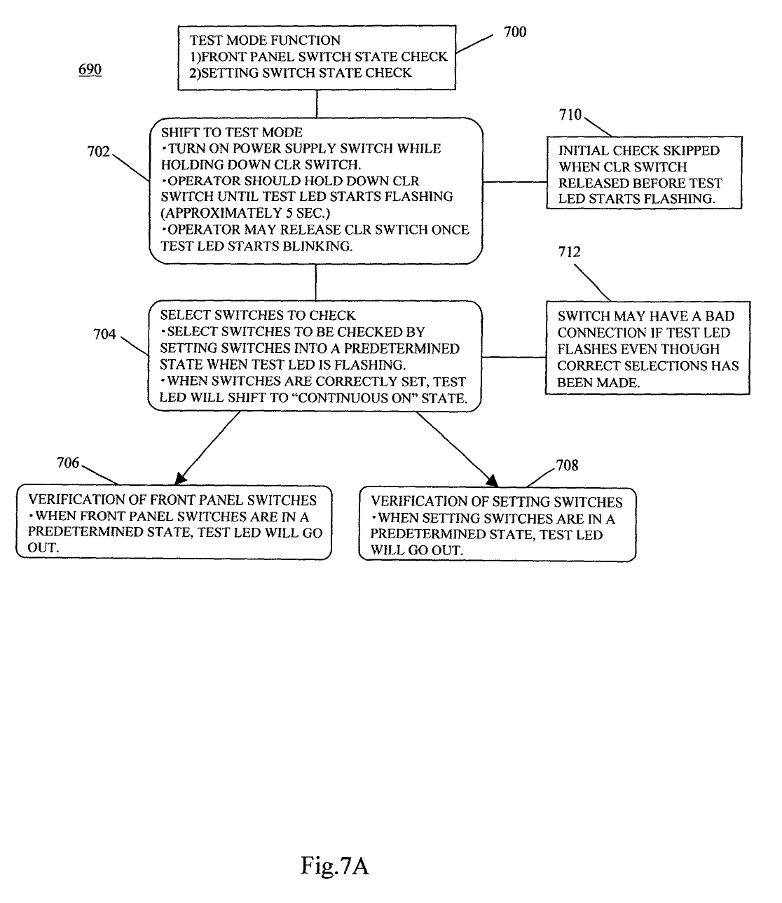

FIG. 6 is a flow chart 590 showing the test mode process of the present invention.

Referring now to FIG. 6, when the power supply switch 48 turns on, the test LED 44a turns on (600). Next, it is checked whether or not a CLR switch 64 has been pressed (602). If the CLR switch 64 has not been pressed, then an initial check of the data transmission device is executed (604), and the data transmission device will shift into a normal state (606), not a test mode. On the other hand, if the CLR switch 64 has been pressed, then the data transmission device 20 will check to see whether or not the CLR switch 64 has been pressed again (608). If the CLR switch 64 has not been pressed, the data transmission device 20 will shift into a normal state (606).

If the CLR switch 64 has been pressed, the device control module 40 waits one second (610) and checks to see if more than 5 seconds have elapsed since the CLR switch 64 was pressed (612). If the CLR switch 64 is held down for 5 seconds continuously, the device control module 40 would detect that the CLR switch 64 is pressed after the 5 second period has passed. In this case, the data transmission device 20 will shift into testing mode (614). If the device control module 40 does not detect that CLR switch 48 was not pressed after 5 seconds has passed, the data transmission device will shift into a normal state (606).

When the testing mode begins, the test LED 44a will go on (618) after 200 milliseconds period elapsed (616). Then the state of the setting switches will be checked to see if the state is “10101010”, that is, whether or not the settings are alternately on and off (620). If the state of the setting switches is as above, it is determined that the setting switches are subjects for testing. If the state of the setting switches is not as above, the test LED 44a will go out (634) after waiting 200 ms (632), and the device control terminal 40 determines a state of the front panel switches is in “01011001” state or not. If the state of the front panel switches is “01011001”, it is determined that the front panel switches are subjects for testing.

When it is determined that the setting switches are subjects for testing, the device control module 40 then checks the state of the setting switches. If the setting switches are in “10101010” states as shown in FIG. 4 (622), the device control module 40 turns off the test LED 44a (626), otherwise it remains on (628). If the device control module 40 determines that the setting switches are not in “10101010” state, then it checks as is the setting switches are in “01010101” state. If the state of the setting switches is “01010101”, then the test LED 44a turns off (626), otherwise it remains on (628).

After the test LED 44a went off, an operator would change the setting switches to “01010101” state, if the operator firstly sets the setting switches to “10101010” state. Then the device control module 40 checks if the setting switches are in “01010101” state or not (624). If the setting switches are in “01010101” states, the device control module 40 turns the test LED 44a off (626), otherwise it turns on (628) until the device control module 40 detects “01010101” state.

In this embodiment, an operator needs to operate two tests, both “10101010” test and “01010101” test. It is up to an operator which test to operate first, and the other test second.

On the other hand, if it is determined that the front panel switches are subjects for testing, the device control module 40 checks if the state of the front panel switches is “01011001” or not (638). If it is, then the test LED 44a tuns off (630), otherwise remains on. After the determination, the device control module 40 checks a state of the front panel switches in “10100110” or not (640). If the state is in “10100110”, the test LED 44a turns off (630), otherwise it remains (or turns) on (642).

As same as the test for the setting switches, an operator needs to operate two tests, “01011001” and “10100110”, for the front panel switches.

In this way, line connections of switches are tested for shorts.

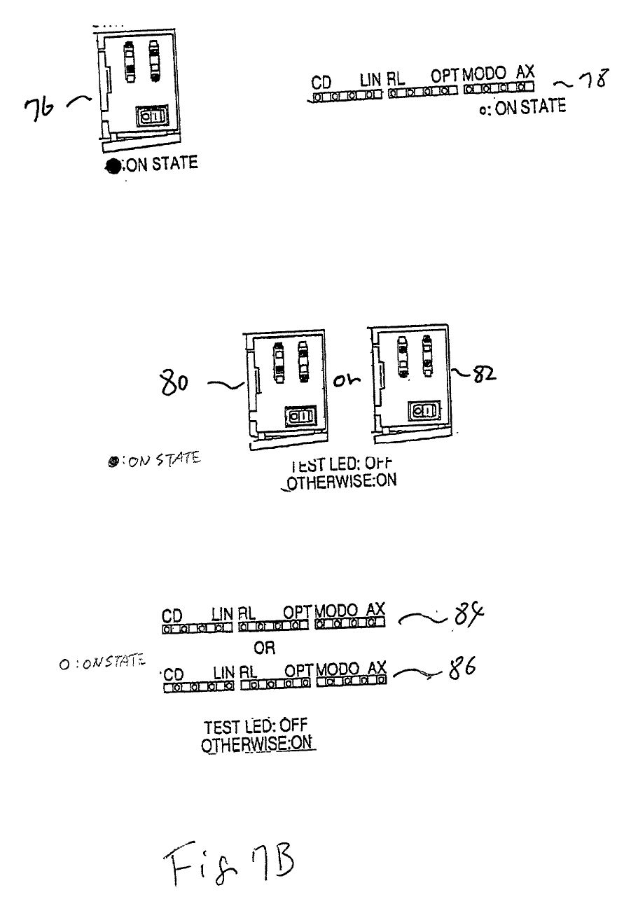

FIG. 7A shows a procedure 690 performed by an operator for testing these line connections of switches as described above for shorts. Further, FIG. 7B shows conditions of front panel switches 20 shown in FIG. 2 and setting switches 66, 68, 70 shown in FIG. 4 while the test as the procedure 690 shown in FIG. 7A is performed.

The test mode is a mode to check the front panel switch state and check the setting switch state as described above (700 of FIG. 7A). To shift the data transmission device 20 into the test mode, an operator would turn on the power supply switch 48 while holding the CLR switch 64 down (702, corresponds to processes 608-610-612-614 of FIG. 6). An operator would hold down the CLR switch 64 until the test LED 44a begins to flash. In this embodiment of the present invention, it takes about 5 seconds for the test LED 44a to be lit after the CLR switch is held down. After the test LED 44a starts flashing, or blinking, an operator may release the CLR switch 64. Meanwhile, if an operator release the CLR switch 64 before the test LED 44a starts flashing, an initial check will be skipped. Then the data transmission device shifts into a normal state (710, corresponds to processes 602-608-606 of FIG. 6) without testing connection of the switches.

A flashing of the test LED 44a indicates that the data transmission device 20 shifts into the test mode. Description “TURN ON TEST LED 44A” of 618 and 634 of FIG. 6 corresponds to this flashing. Then an operator may select the switch he or she wants to run the test, by turning the front panel switches or the setting switches into a predetermined state (704). If an operator selects the front panel switch for testing, the operator should turn on and off the front panel switches as shown in 76 of FIG. 7B (corresponds to process 636 of FIG. 6). If an operator wants setting switches to be tested, the operator should turn on and off the setting switches as shown in 78 of FIG. 7B (corresponds to process 620 of FIG. 6). When the front panel switches are correctly set in the state as shown in 76 of FIG. 7B (after the process 636), or the setting switches are set in the state as shown in 78 of FIG. 7B (after the process 620), the test LED 44a will turn on continuously from flashing.

If the test LED still flashes although the switches are set into the state as shown in 76 or 78 of FIG. 7B, any of the switches may have a bad connection (712). In this case, the operator may need to check the switches to determine whether the connection is good or not.

After the test LED 44a turned on continuously, the device control module 40 will start to check a state of the selected switches, and an operator will set the front panel switches or the setting switches into a required state. When the front panel switches are selected, then process 706 will be processed by an operator.

Examples of state of the front panel switches are shown in 80 and 82 of FIG. 7B. An operator would turn on and off each of the front panel switches in a required conditions as shown in 80 or 82 of FIG. 7B, then the device control module 40 will monitor the states of these switches. When an operator selected a state that shown in 80, then the device control module 40 should determine the states of switches as “01011001” (corresponds to process 638 of FIG. 6). Similarly, when an operator selected a state that shown in 82, the device control module 40 should determine the states as “10100110” (corresponds to process 640 of FIG. 6).

When the device control module 40 determines that the state of the front panel switches is “01011001” or “10100110”, then it turns the test LED 44a off (corresponds to process 630 of FIG. 6), otherwise the test LED 44a remains on (corresponds to process 640 of FIG. 6).

When the test LED 44a turned off, this means a first test is successful, an operator then selects an state that is opposite to the state he or she had selected, and the second test is operated by the device control module 40. For example, when an operator firstly selected a state as shown in 82, the he or she would select a state as shown in 84 after the test LED turned off, and vice versa. When the device control module 40 determines that the state of the front panel switches is either “10100110” or “01011001”, the test LED 44a turns off, but otherwise it turns on. While an operator changes a state of front panel switches from one to the other, the test LED 44a would temporarily turns on, as the switches are not in the required conditions.

When the test LED turns off in both first and second test, it means that the connections of the front panel switches are good. On the other hand, if the test LED 44a remains on even if an operator sets the front panel switches correctly, or the test LED 44a turns off before an operator sets the switches in a predetermined state, it means that any of the front panel switches is shorted, or may have a bad connection.

Similarly to the testing of the front panel switches, process 708 is processed when an operator selects the setting. 84 and 86 of FIG. 7B show examples of the state of the setting switches for testing. An operator will turn these switches in either way as shown in 84 or 86 to test the setting switches. When the state as shown in 84 is selected, then the device control module 40 reads in the state as “10101010 10101010 10101010”, as same as shown in FIG. 4 (corresponds to process 622 of FIG. 6). When the state as shown in 86 is selected, the device control module 40 reads in the state as “01010101 01010101 01010101” (corresponds to process 624 of FIG. 6).

If the device control module 40 determines that the switches are in the predetermined condition, then the test LED 44a would be turned off (corresponds to process 626 of FIG. 6), otherwise it remains on (corresponds to process 628 of FIG. 6).

After the test LED 44a turned off (or the first test is successful), then an operator would change the state of the setting switches to the opposite state to operate the second test. For example, when an operator firstly selected a state as shown in 84, he or she would turn the setting switches in a state as shown in 86. When the test LED turns off in both tests, the test of the setting switches is successful. In this manner, connection of the setting switches is tested.

The test mode ends when the power supply is turned off. If an operator wish to change switches to be tested from one to the other, from the front panel switches to the setting switches for example, it is required to turn the power supply off once, then initialize the test mode again.

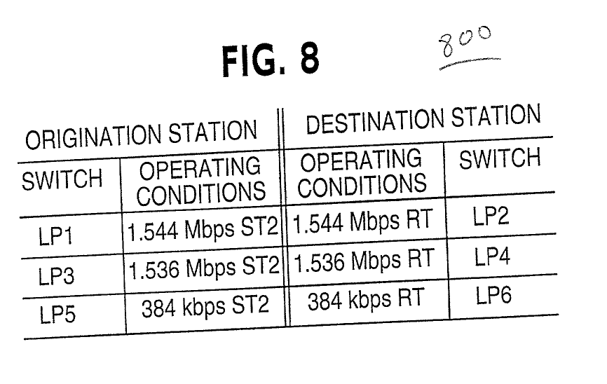

FIG. 8 shows an example of an assignment of operating conditions 800 to each of the switches LP1-LP6 of the front panel switches of the data transmission device 20 of the present invention. Operating conditions may include such as shown in FIG. 3. These operating conditions are assigned to each of the front panel switches in advance, and are recorded in the device control module 40, or in a memory within the data transmission device 20. To submit a counter-test, an operator only needs to select on of the front panel switches, but does not need to set up corresponding operating conditions manually.

The device control module 40 monitors the state of the LP switches during counter-tests. If one of the LP switches is set to on, the device control module 40 determines which LP switch is turned on, then the operating conditions assigned to the switch are to be set in the DTE control module 28, the modulator module 30 and the demodulator module 36. By assigning operating conditions for each of the front panel switches in advance, it is easier to make the settings when running counter-tests, and mistake are reduced.

Corresponding switches are selected on both sides of communication lines 22. For example, if the LP1 switch is selected at the origination station, or a data transmission device 20 of the one side, LP2 switch is selected at the destination station, or a data transmission device 20 of the other side. In this manner, counter test can be run on between two data transmission devices 20. LP3 and LP4correspond to each other, and similarly LP5 and LP6 correspond to each other. In FIG. 8, “ST” means sending terminal which sends a test pattern signal to the other terminal, and “RT” means receiving terminal. Three sets of test modes are corresponding to the different transmission speed. The device control module 40 contains operation conditions to be set to the DTE control module 28 and modulation/demodulation module 30, 38, for example, corresponding to each of the test modes.

A tester can be connected to the DTE port 24 or the data transmission device 20 in substitution of a data terminal. In a test mode, a test pattern signal may be sent out to the other data transmission device through communication lines 22. By determining if any bit errors occurs by using the tester, it is possible to check whether or not the device is in a normal state. Also, by turning on the ERRCHK 62 switch of the front panel 46 for the origination station and destination station, the data transmission device 20 sends out a test pattern and will check the bit error status by itself, without using any tester.

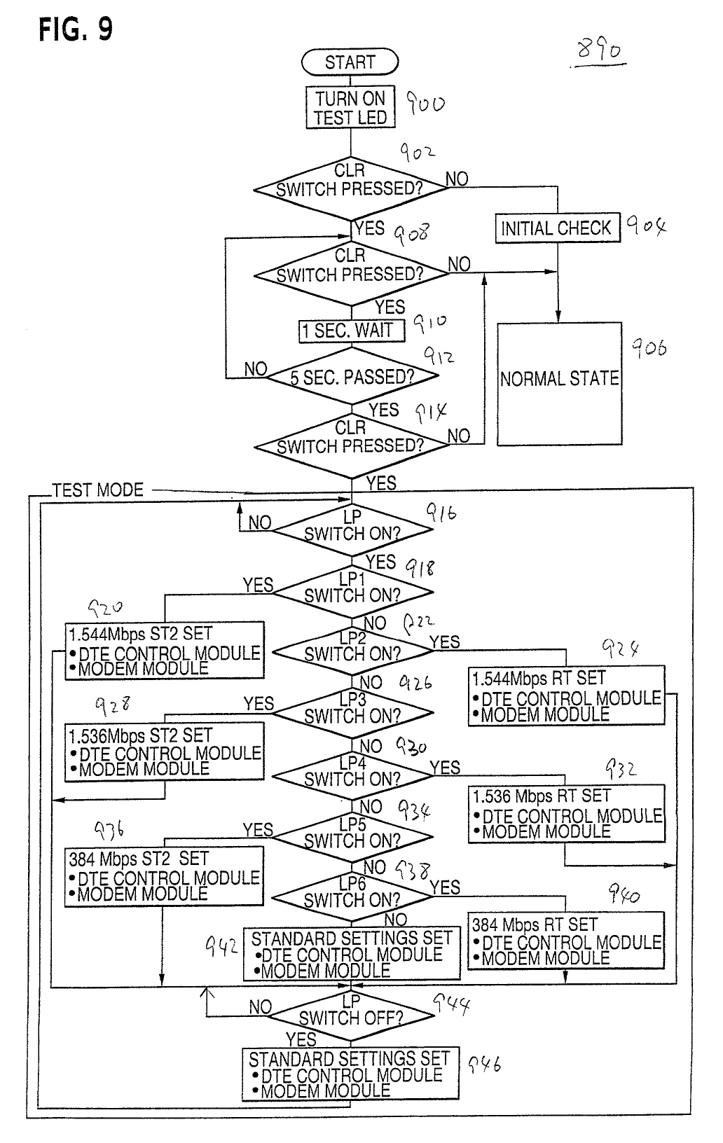

FIG. 9 is a flow chart 890 describing the process for the aforementioned counter test.

The procedures are as same as described in FIG. 6 until testing mode begins (914), so no description will be offered for these steps. That is, process 900 of FIG. 9 corresponds to process 600 of FIG. 6, 902 corresponds to 602, 904 corresponds to 604, 906 corresponds to 606, 908 corresponds to 608, 910 corresponds to 610, 912 corresponds to 612, and 914 corresponds to 614. When the test begins, the device control module 40 determines if any of the LP switches is switched on (916). In the event that none of the LP switches is on, the process of counter test of FIG. 9 will end.

If the device control module 40 determines that any of the LP switches is on, then a testing mode corresponding to the selected LP switch will be started. When the device control module 40 determines that the LP1 switch is selected (918), the device control module 40 sets required operating conditions corresponding to “1.544 Mbps” mode to the DTE control module 28 and modulation/demodulation module 30, 36 (920). Similarly, when the device control module 40 determines that the LP2 switch is selected (922), the device control module 40 sets required operating conditions corresponding to “1.544 Mbps RT” mode to both the DTE control module 28 and modulation/demodulation module 30, 36.

When the device control module 40 determines that LP3 switch is selected (926), the device control module 40 sets required operating conditions corresponding to “1.536 Mbps ST2” mode to the DTE control module 28 and modulation/demodulation module 30, 36 (928). When the device control module 40 determines that LP4 switch is selected (930), then the device control module 40 set required operating condition corresponding to “1.536 Mbps RT” to the DTE control module 28 and modulation/demodulation module 30, 36 (932).

When the device control module 40 determines that LP3 switch is selected (934), the device control module 40 sets required operating conditions corresponding to “384 kbps ST2” mode to the DTE control module 28 and modulation/demodulation module 30, 36 (936). When the device control module 40 determines that LP4 switch is selected (938), then the device control module 40 set required operating condition corresponding to “384 kbps RT” to the DTE control module 28 and modulation/demodulation module 30, 36 (940).

In each case, a counter test between two data transmission device 20 corresponding to a selected switch is operated after required operating condition is set to the data transmission device 20.

If none of the switches LP1-LP6 is on, or if any of the other switches in the front panel are on, the standard settings will go into effect (942). Standard settings will also go into effect (946) if the LP switches are still on after counter test ends, and the selected LP switch turns off (944).

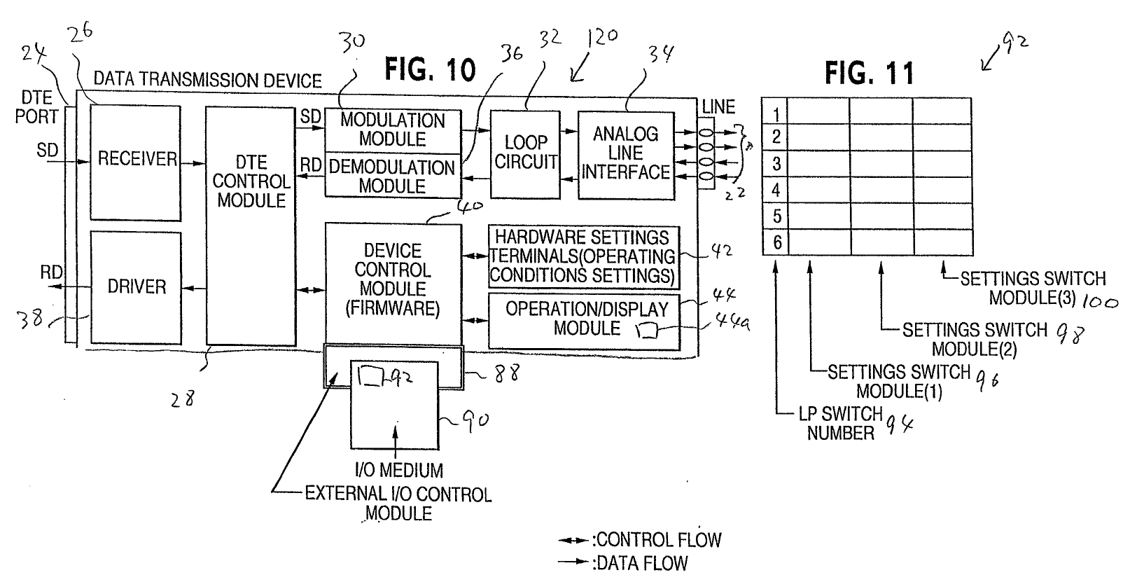

FIG. 10 shows a data transmission device 120 of another embodiment of the present invention. A basic structure of the data transmission device 120 is similar to the data transmission device 20 shown in FIG. 1, and the detailed description of the similar portions is omitted. In addition to the data transmission device 20 of FIG. 1, the data transmission device 120 of FIG. 10 comprises I/O control module 88. An I/O control module 88 shown in FIG. 10 is an external device, but it may be an internal module. The I/O control module 88 could be a disc drive, or any other kind of conventional device that can read information recorded on a recording medium, or “I/O medium 90, as shown in FIG. 10, and its operation is controlled by the device control module 40.

The I/O medium 90 could be a magnetic disc such as a floppy disc, or any other conventional recording medium such as a memory card, a smart card and so on. The I/O medium 90 stores a file 92, named such as “tsetSW.dat”, which specifies operating conditions of the data transmission device 120 for a counter test.

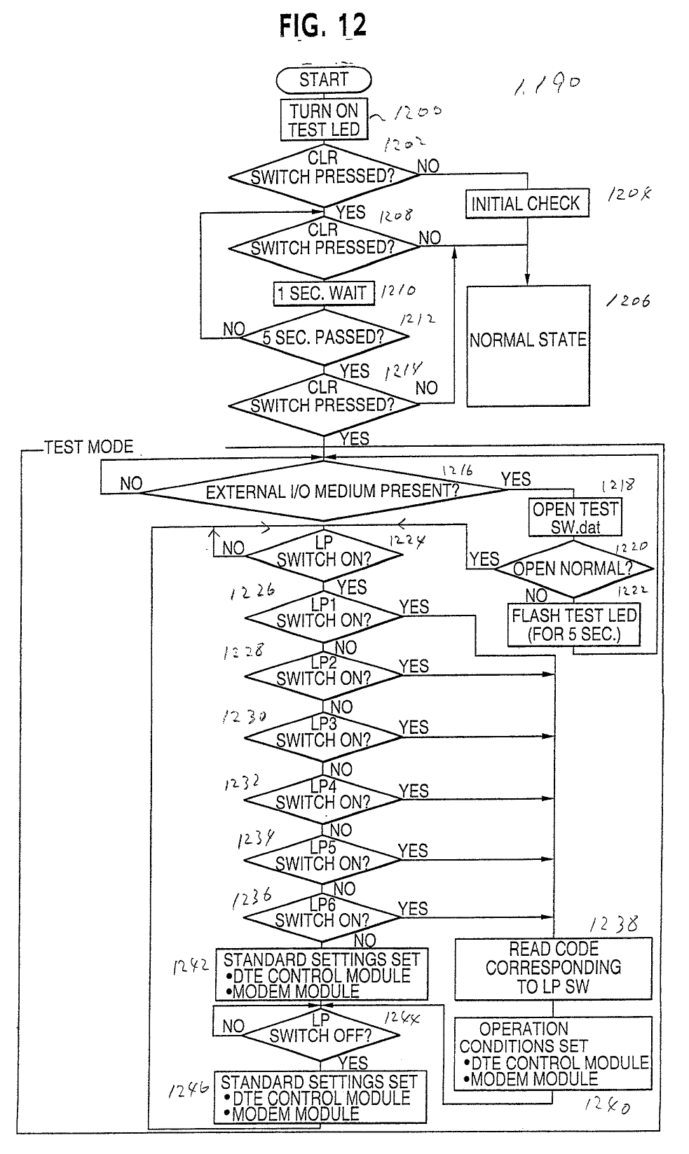

FIG. 11 shows an example of a file 92 recorded in the I/O medium 90. 94 denote an LP switch number, and each of the LP switch numbers corresponds to a type of counter test as shown in FIG. 8. Further, 96, 98 and 100 are the area for recording settings of setting switch modules indicating states of each of the setting switches shown in FIG. 3 for each of the LP switches. This information 96, 98, 100 is recorded in the file 92 in a form of bit rows, and each bit indicates whether each of the corresponding setting switches should be turned on or turned off. Among of these, 96 corresponds to setting switch module 66, 98 corresponds to setting switch module 68, and 100 corresponds to setting switch module 70.

When an operator selects one of the LP switches shown in FIG. 2 for initiating a counter test, the device control module 40 searches a file 92 recorded in the I/O medium 90, and reads in corresponding setting information from the file 92.

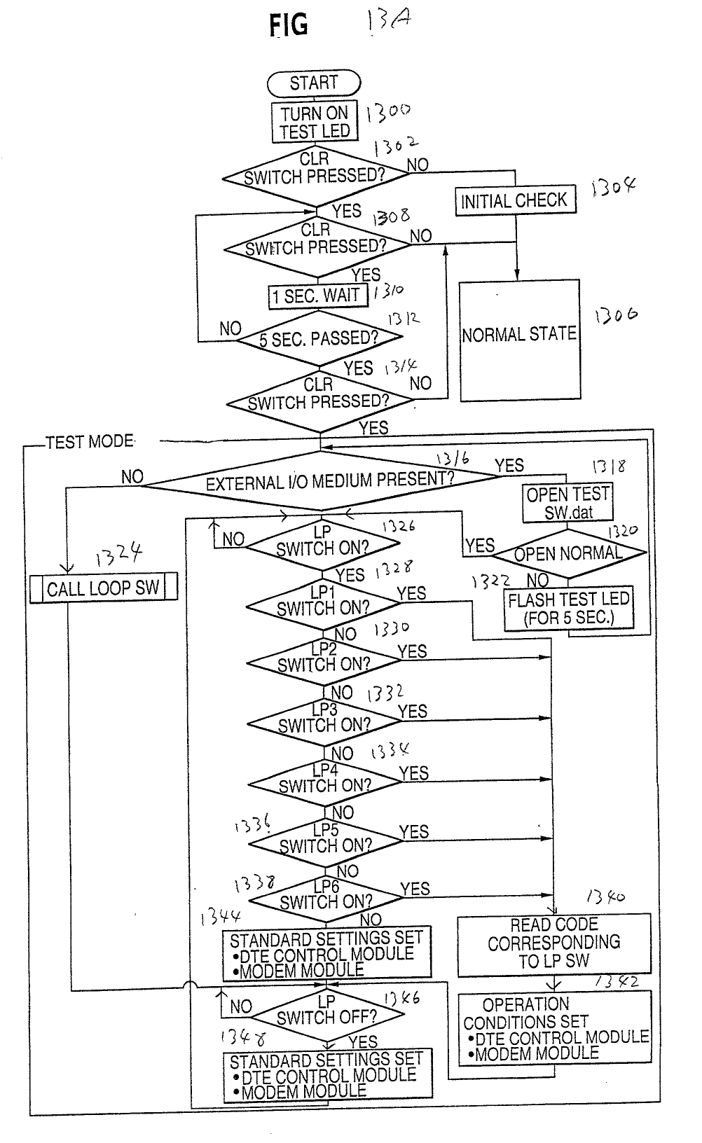

FIG. 12 is a flow chart 1190 showing a process of an embodiment of the present invention related to the operating condition settings using an external I/O medium 90 shown in FIG. 10.

Referring now to FIG. 12, when the data transmission device 120 is shifted to a test mode, the device control module 40 will check to see whether the external I/O module 90 exists (1216). If an external I/O medium 90 exists, a setting file 92 inside of “testSW.dat” will be opened (1218). If the file 92 is opened normally (1220), the device control module 40 will identify any of the LP switches is switched on (1224). When the file 92 cannot be opened properly, the test LED 44a will blink for five seconds to notify an operator of that fact (1222).

When the device control module 40 determines that any of the LP switches turned on (1226 to 1236), the device control module 40 reads code (bits) recorded in area 96, 98 and 100 of file 92 correspond to the selected LP switch (1238). Then the device control module 40 sets operation conditions as read from the file 92 to the DTE control module 28, modulation/demodulation module 30, 36 or any other modules (1240). After the setting of operating conditions, counter tests corresponding to the selected LP switch is started. When the device control module 40 determines that none of the LP switches is selected, then a standard setting is done.

After a counter tests end, it is determined if the LP switch is turned off or not (1244). If it is, then a standard setting is done (1246).

By using such an I/O medium 90, an operator does not need to set up all necessary operating conditions to the data transmission device manually. Therefore, a possibility of making mistake while trying to set up operating conditions would be reduced.

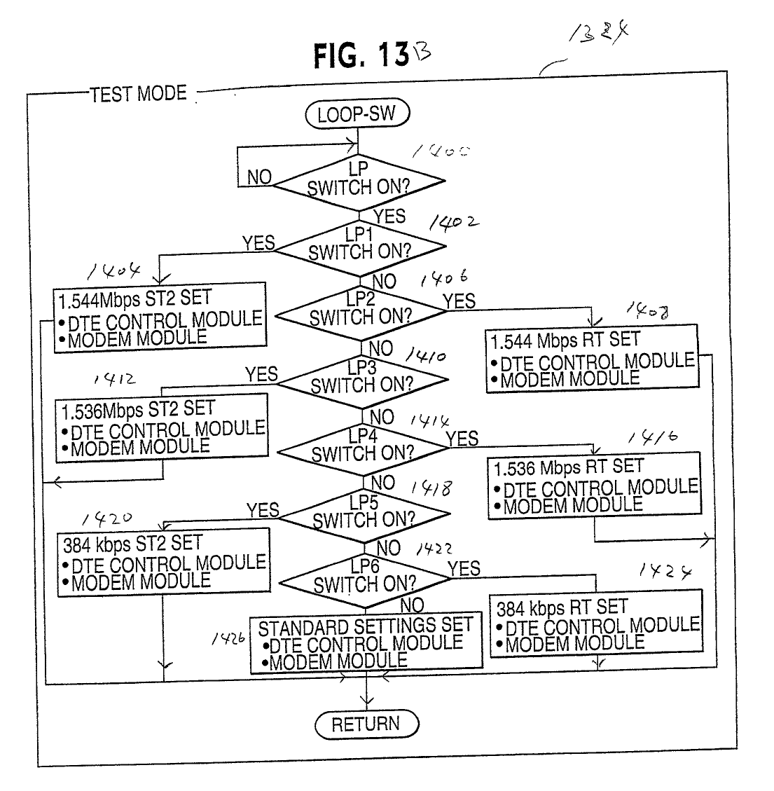

FIG. 13A is a flow chart 1290 describing another example of setting the operating conditions of the present invention. The difference between FIG. 12 and FIG. 13A is an addition of process 1324. That is, process 1300 of FIG. 13A corresponds to process 1200 of FIG. 12. Similarly, 1302 corresponds to 1202, 1304 corresponds to 1204, 1306 corresponds to 1206, 1308 corresponds to 1208, 1310 corresponds to 1210, 1312 corresponds to 1212, 1314 corresponds to 1214, 1316 corresponds to 1216, 1318 corresponds to 1218, 1320 corresponds to 1220, 1322 corresponds to 1222, 1326 corresponds to 1224, 1328 corresponds to 1226, 1330 corresponds to 1228, 1332 corresponds to 1230, 1334 corresponds to 1232, 1336 corresponds to 1234, 1338 corresponds to 1236, 1340 corresponds to 1238, 1342 corresponds to 1240, 1344 corresponds to 1242, 1346 corresponds to 1244 and 1348 corresponds to 1246.

When the device control module 40 determines that an external I/O medium 90 is not present, then the process of “CALL LOOP SW” (1324) will be run. I n this case, operating conditions assigned to a selected LP switch would be set up to the data transmission device.

FIG. 13B shows a detailed process of 1324 shown in FIG. 13A. As shown in FIG. 13B, process 1324 is similar to the process 916 through 946 shown in FIG. 9. FIG. 13A shows a process in which processes shown in FIG. 9 and FIG. 12 are combined. Therefore, even though an external I/O medium 90 is not present, operating conditions for a counter test can be set up in the process of FIG. 13A.

When the device control module 40 determines that an external I/O medium is not present in process 1316 of FIG. 13A, then the device control module 40 sees if any of the LP switch is turned on (1400). When LP1 switch is on (1402), then the device control module 40 set operation conditions related to “1.544 Mbps ST2” mode to the DTE control module 28, and to the modulation module 30 and the demodulation module 36 (described as “modem module” in FIG. 13B) (1404).

When LP2 switch is on (1406), then the device control module 40 set operation conditions related to “1.544 Mbps RT” mode to the DTE control module 28, and to the modulation module 30 and the demodulation module 36 (1408).

When LP3 switch is on (1410), then the device control module 40 set operation conditions related to “1.536 Mbps ST2” mode to the DTE control module 28, and to the modulation module 30 and the demodulation module 36 (1412).

When LP4 switch is on (1414), then the device control module 40 set operation conditions related to “1.536 Mbps RT” mode to the DTE control module 28, and to the modulation module 30 and the demodulation module 36 (1416).

When LP5 switch is on (1418), then the device control module 40 set operation conditions related to “384 kbps ST2” mode to the DTE control module 28, and to the modulation module 30 and the demodulation module 36 (1420).

When LP6 switch is on (1422), then the device control module 40 set operation conditions related to “384 kbps RT” mode to the DTE control module 28, and to the modulation module 30 and the demodulation module 36 (1422).

When none of the LP switches is selected, then the device control module sets the DTE control module 28 and the modulation module 30 and the demodulation module 36 into a standard setting.

In this way, the embodiments of the present invention make it possible to reduce the increased amount of effort for evaluations using the testing mode. It also makes it extremely easy to set up the operating conditions and to prevent set up errors.

The many features and advantages of the invention are apparent from the detailed specification and, thus, it is intended by the appended claims to cover all such features and advantages of the invention which fall within the true spirit and scope of the invention. Further, since numerous modifications and changes will readily occur to those skilled in the art, it is not desired to limit the invention to the exact construction and operation illustrated and described, and accordingly all suitable modifications and equivalents may be resorted to, falling within the scope of the invention.

What is claimed is:

1. A test method of a device having a plurality of switches comprising:
reading a state of said switches;
determining whether a read state of said switches satisfies a predetermined state; and
notifying results of said determination.

2. The test method according to claim 1 further comprising displaying said results of said determination, by turning off said display when said read state of said switches corresponds to said pre-determined state.

3. A method for setting operating conditions for testing a device having a plurality of switches, comprising:
determining which of said switches is turned on;
setting up operating conditions assigned to a switch which is turned on; and
operating a test of said device based on said set up operating conditions.

4. The method for setting operating condition according to claim 3, wherein a different type of test modes are assigned to said switches, and said test of said device is operated in a test mode corresponding to a switch which is turned on.

5. A method for testing a data transmission device, comprising:
determining which of a plurality of switches is selected;
reading operating condition information corresponding to a selected switch from a recording medium;
setting up operating conditions read from said recording medium to components of said data transmission device; and
submitting test of said data transmission device in a test mode corresponding to said selected switch.

6. A device capable of setting operating conditions comprising:
a setting switch which an operating condition can be assigned;
a unit reading content stored in a recording medium; and
a unit assigning operating conditions read from said recording medium to said setting switch.

7. A device capable of setting operating conditions comprising:
a setting switch to which an operating condition is assigned in advance;
means for reading content stored in a recording medium;
means for detecting a presence of said recording medium; and
means for setting an operating condition read in from said recording medium when said recording medium is present, and setting operation condition corresponding to a switch that is turned on when there is no recording medium.

8. A data transmission device comprising:
a plurality of switches in which different testing mode is assigned to each of said switches;
a device controller connected to said switches, and controls an operation of said data transmission device; and
a recording medium contains operating conditions of said data transmitter corresponding to each of said switches;
wherein when one of said switches is selected, said device controller reads operating conditions corresponding to a selected switch from said recording medium, sets up read operating conditions to components of said data transmission device, and submits a test in a testing mode corresponding to said selected switch.

9. The data transmission device according to claim 8, wherein;
said recording medium is an internal recording medium contained within said data transmission device.

10. A device capable of setting operating conditions comprising:
a plurality of first switches in which a different type of operating mode is assigned to each of said first switches;
a plurality of second switches for setting operating conditions of said device;
a recording medium contains on-off status information of each of said second switches corresponding to each type of operating modes;
a device controller connected at least to said first switches;
wherein said device controller determines which of said first switches is selected, reads on-off status information corresponding to a selected first switch from said recording medium, and sets up operating conditions to components of said device as if said second switches are in an on-off status read from said recording medium.

11. The device according to claim 10, wherein said recording medium is an external recording medium.

12. A data transmission device comprising:
a plurality of switches in which different testing mode is assigned to each of said switches;
a device controller connected to said switches, and controls an operation of said data transmission device; and
an external medium control unit, controlled by said device controller, and reading information recorded within an external recording medium;
wherein when one of said switches is selected, said device controller controls said external medium control unit to read operating condition information corresponding to said selected switch from said recording medium, sets up read operating conditions to components of said data transmission device, and submits a test in a testing mode corresponding to said selected switch.

13. The data transmission device according to claim 12, wherein:
said external medium control unit detects a presence of said external recording medium; and
said device controller controls said external medium controller to read operating conditions recorded in said recording medium when said recording medium is present, and reads operating conditions recorded inside of said data transmission device when said recording medium is not present.

14. A device comprising:
a plurality of switches, at least one of those is used to initiating a test mode;
a controller at least connected to said switches, controls an operation of said device and, reads a status of said switches when said test mode is initiated; and
an indicator controlled by said controller;
wherein said controller determines said read status of said switches as said read status satisfies a predetermined status or not, and controls said indicator to notify a result of a determination.

15. The device according to claim 14, wherein:
said indicator is a display; and
said controller controls said indicator to display information in a first manner when it is determined that said switches are in a predetermined status, and to display information in a second manner which is different from said first manner when it is determined that said switches are not in a predetermined status.

16. A device comprising:
a first switch module and a second switch module;
a device control unit connected to said first switch module and said second switch module;
wherein said device control unit determines which of said first and second switch module is selected when said device is in a test mode, and operates a test of the selected switch module.
